(19) United States
(12) Patent Application Publication
(10) Pub. No.: US 2017/0366376 A1
(43) Pub. Date: Dec. 21, 2017

(54) ANALOG FRACTIONAL-N PHASE-LOCKED LOOP

(71) Applicant: Marvell World Trade Ltd., St. Michael (BB)

(72) Inventors: Haisong Wang, Crissier (CH); Xiang Gao, Fremont, CA (US); Olivier Burg, Lausanne (CH); Cao-Thong Tu, Preverenges (CH)

(21) Appl. No.: 15/629,509

(22) Filed: Jun. 21, 2017

Related U.S. Application Data
(60) Provisional application No. 62/352,899, filed on Jun. 21, 2016.

(51) Int. Cl. H04L 27/20; H03L 7/197; H03L 7/087; H04L 25/03; H03L 7/081

(52) U.S. Cl. CPC H04L 27/2017; H04L 25/03834; H03L 7/081; H03L 7/087; H03L 7/1976

(57) ABSTRACT

An analog fractional-N phase-locked loop includes an oscillator loop having a reference input, a feedback input, and a loop output, and a fractional feedback divider configured to divide signals on the loop output by a divisor. Output of the fractional feedback divider is fed back to the feedback input. A compensation circuit is coupled to, and configured to apply a time delay to, the reference input or the feedback input, to compensate for delay introduced by the fractional feedback divider. The compensation circuit may be a digital-to-time converter configured to convert a digital delay signal into the time delay. The digital-to-time converter may be coupled to the reference input to delay signals to match feedback delay introduced by the fractional feedback divider, or to the feedback input to subtract the time delay to cancel feedback delay introduced by the fractional feedback divider.

### CROSS REFERENCE TO RELATED APPLICATION

This claims the benefit of copending, commonly-assigned U.S. Provisional Patent Application No. 62/352,899, filed Jun. 21, 2016, which is hereby incorporated by reference herein in its entirety.

### FIELD OF USE

This disclosure relates to an analog fractional-N phase-locked loop, and more particularly to quantization noise cancellation in an analog fractional-N phase-locked loop.

### BACKGROUND

The background description provided herein is for the purpose of generally presenting the context of the disclosure. Work of the inventors hereof, to the extent the work is described in this background section, as well as aspects of the description that may not otherwise qualify as prior art at the time of filing, are neither expressly nor impliedly admitted to be prior art against the present disclosure.

A phase-locked loop (PLL) typically is used to lock a signal to a reference signal—i.e., to generate an output signal that has a lock-step phase difference relative to the phase of the input reference signal. In a basic phase-locked loop, the output of a variable oscillator (e.g., a voltage-controlled oscillator, or VCO) is looped back to the input of a phase-frequency detector (PFD), which also has a reference signal as another input. The PFD examines the phase and frequency differences between the loop output and the reference signal, and generates a control signal that adjusts the variable oscillator to align the phase and frequency of the loop output with the phase and frequency of the reference signal.

The feedback loop of a PLL may include a divider circuit. Dividing the fed-back output by an integer N has the effect of multiplying the output frequency by N relative to input reference frequency. If N is an integer, the divider circuit may be a simple modulo-N counter, producing one output signal for every N input signals. Fractional values of N also can be achieved by dynamically changing the integer value so that, on average over a period, the desired fraction is achieved. One way to accomplish such a result is to use a sigma-delta modulator to control the duty cycle of the divider.

However, a sigma-delta modulator typically introduces quantization noise, as the result of a rounding error when the signal-delta modulator provides a closest integer to the divider circuit to approximate a desired fractional divisor. The quantization noise is thus present in the control signal from the sigma-delta modulator that controls the duty cycle of the divider circuit, and thus the quantization noise may in turn affect the accuracy of the output signal of the divider circuit. Such quantization noise will be low-pass filtered by the PLL loop filter, meaning that the loop bandwidth would have to be limited to avoid excessive phase noise. In addition, depending on the order of the sigma-delta modulator, the resulting phase error at the PFD/charge pump (PFD/CP) combination will introduce more in-band noise than in the integer-N case. Also, conventional techniques to reduce quantization noise tend to linearize the PFD/CP output, which in this case could increase noise and also result in worse spur performance (i.e., mismatch between the reference edge and the free-running signal edge).

### SUMMARY

An analog fractional-N phase-locked loop according to implementations of the subject matter of this disclosure includes an oscillator loop having a reference input, a feedback input, and a loop output, and a fractional feedback divider configured to divide signals on the loop output by a divisor, wherein output of the fractional feedback divider is fed back to the feedback input, and a compensation circuit coupled to one of the reference input and the feedback input, the compensation circuit configured to apply a time delay to the one of the reference input and the feedback input to compensate for delay introduced by the fractional feedback divider.

In such an implementation, the compensation circuit may be a digital-to-time converter configured to convert a digital delay signal into the time delay. The digital-to-time converter may be coupled to the reference input and configured to delay signals on the reference input by the time delay to match feedback delay introduced by the fractional feedback divider. The digital-to-time converter may be coupled to the feedback input and subtract the time delay from signals on the feedback input to cancel feedback delay introduced by the fractional feedback divider.

In a variant of such implementation, the oscillator loop may further include a loop filter configured to filter out frequency noise components, and the digital delay signal to control the digital-to-time converter may be derived based at least in part on an output of the loop filter.

In such a variant, the analog fractional-N phase-locked loop may further include an analog integrator configured to integrate the output of the loop filter to generate an analog delay signal, and an analog-to-digital converter configured to digitize the analog delay signal thereby to provide the digital delay signal to control the digital-to-time converter.

In that variant, a sign signal, representative of direction of phase mismatch, may be derived from the fractional feedback divider, the oscillator loop may further include a switch configured to, based on the sign signal, select a path from between two paths through the loop filter, and the analog integrator may be connected to outputs of both of the two paths through the loop filter.

In that variant, an error signal, representative of delay introduced by the fractional feedback divider, may be output by the fractional feedback divider, the loop filter may be a sample-and-hold low-pass filter including a sample-and-hold switch, and the analog fractional-N phase-locked loop may further include a comparator connected across the sample-and-hold switch to derive a sign signal, and a correlator configured to multiply the sign signal by the error signal to provide the control signal.

In such an implementation, the divisor may include a fractional value, and the fractional feedback divider may include a feedback divider configured to divide signals on the loop output by a respective integral value at each respective clock cycle, and a sigma-delta modulator configured to generate the respective integral value at each respective clock cycle based on the divisor.

A wireless transceiver may include the analog fractional-N phase-locked loop according to such an implementation.

A method according to implementations of the subject matter of this disclosure for operating an analog fractional-N phase-locked loop, including an oscillator loop having a reference input, a feedback input, and a loop output, and having a fractional feedback divider configured to divide signals on the loop output by a divisor, wherein output of the fractional feedback divider is fed back to the feedback input, includes measuring delay introduced by the fractional feedback divider, and compensating for the feedback delay introduced by the fractional feedback divider by applying a time delay to the one of the reference input and the feedback input.

In such an implementation, the measuring may include deriving a digital delay signal representative of the delay introduced by the fractional feedback divider, and the compensating may include converting the digital delay signal to the time delay.

In a variant of that implementation, the compensating may be performed by a digital-to-time converter coupled to the reference input, and may include delaying signals on the reference input to match the feedback delay introduced by the fractional feedback divider.

In a variant of that implementation, the compensating may be performed by a digital-to-time converter coupled to the feedback input, and may include subtracting delay from signals on the feedback input to cancel the feedback delay introduced by the fractional feedback divider.

In such an implementation, the deriving a digital delay signal may be performed based at least in part on an output of a loop filter in the oscillator loop. The deriving a digital value may include performing analog integration at the output of the loop filter, and digitizing a result of the analog integration to provide the digital delay signal. Such an implementation may further include deriving a sign signal, representative of direction of phase mismatch between the reference input and the loop output, from the fractional feedback divider, and selecting a path, based on the sign signal, from between two paths through the loop filter, wherein the analog integration is performed on outputs of both of the two paths through the loop filter.

In such an implementation, the loop filter may be a sample-and-hold low-pass filter including a sample-and-hold switch, and the method may further include deriving a sign signal by comparing voltages on both sides of the sample-and-hold switch, deriving an error signal indicative of a rounding error from the fractional feedback divider, and multiplying the sign signal by the error signal to provide the digital value.

A compensation circuit for an analog fractional-N phase-locked loop including an oscillator loop having a reference input, a feedback input, a loop filter and a loop output, and having a fractional feedback divider in a feedback position between the loop output and the feedback input, according to implementations of the subject matter of this disclosure, includes circuitry that is configured to measure delay introduced by the fractional feedback divider, and circuitry that is configured to compensate for the feedback delay introduced by the fractional feedback divider by applying a time delay to the one of the reference input and the feedback input.

In such an implementation, the circuitry that compensates may include a digital-to-time converter configured to convert a digital delay signal into the time delay. The circuitry that measures may include an analog integrator at an output of the loop filter, and the analog integrator may be configured to integrate the output of the loop filter to generate an analog delay signal. The loop filter may include a sample-and-hold low-pass filter having a sample-and-hold switch, and the circuitry that measures may include a comparator across the sample-and-hold switch, the comparator being configured to generate a sign output from comparison of signals from both sides of the sample-and-hold switch, and correlator circuitry configured to multiply the sign output of the comparator by an error signal from the fractional feedback divider to generate the digital delay signal for the digital-to-time converter.

### BRIEF DESCRIPTION OF THE DRAWINGS

Further features of the disclosure, its nature and various advantages, will be apparent upon consideration of the following detailed description, taken in conjunction with the accompanying drawings, in which like reference characters refer to like parts throughout, and in which:

FIG. 1 shows a first implementation of an analog fractional-N PLL in accordance with the subject matter of this disclosure;

FIG. 2 shows a second implementation of an analog fractional-N PLL in accordance with the subject matter of this disclosure;

FIG. 3 shows a first implementation including circuitry for deriving a delay compensation control signal in accordance with the subject matter of this disclosure, including an analog integrator;

FIG. 4 shows a second implementation including circuitry for deriving a delay compensation control signal in accordance with the subject matter of this disclosure, including a sample-and-hold low-pass filter;

FIG. 5 shows detail of an implementation of a sample-and-hold switch in the implementation of FIG. 4;

FIG. 6 is a flow diagram of an implementation of a method according to the subject matter of this disclosure for cancelling quantization noise in an analog fractional-N PLL;

FIG. 7 is a flow diagram of a first variant of the compensating performed in the implementation in FIG. 6 of a method according to the subject matter of this disclosure;

FIG. 8 is a flow diagram of a second variant of the compensating performed in the implementation in FIG. 6 of a method according to the subject matter of this disclosure; and

FIG. 9 is a schematic representation of a transceiver incorporating an analog fractional-N PLL according to the subject matter of this disclosure.

### DETAILED DESCRIPTION

Known techniques for cancelling quantization noise in an analog fractional-N PLL involve injecting the inverse of the quantization noise at the charge pump output to cancel the quantization noise. This doubles the amount of quantization noise in the device, including the original quantization noise in the feedback loop and the inverted quantization noise used for cancellation. This also significantly increases—in some cases doubles—the area subject to the quantization noise, because circuit area is required to measure and inject the quantization noise to be cancelled. In addition, one technique for injecting the inverse of the quantization noise involves a current digital-to-analog converter (current DAC) which must have good linearity to achieve proper cancellation, and in some cases also introduces more phase noise and degrades reference spur performance.

In accordance with implementations of the subject matter of this disclosure, an error cancellation signal is introduced at an input of the PFD. The error cancellation signal can be introduced on the PFD reference input. The error cancellation signal also can be introduced on the feedback loop input, as long as the error cancellation signal is downstream of the feedback divider. As a result, less error is present at the PFD and charge pump, and therefore PFD/CP linearity requirements may be relaxed. Charge pump ON time also could be reduced, so that this technique reduces the charge pump phase noise contribution rather than increasing the charge pump phase noise contribution as in other quantization noise cancellation techniques.

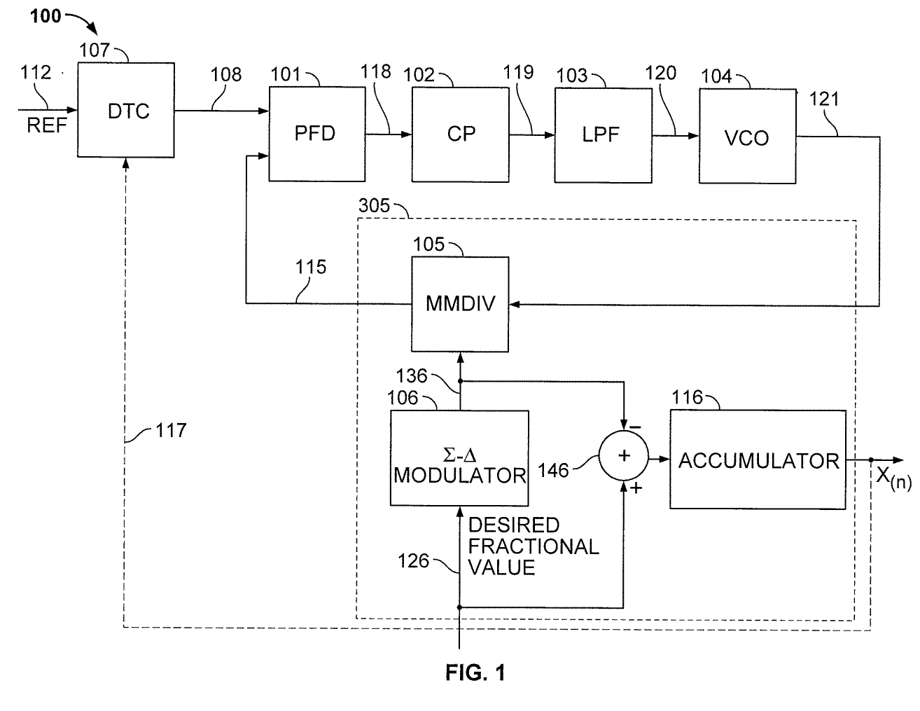

One implementation of an analog fractional-N PLL 100 according to the subject matter of this disclosure is shown in FIG. 1. Analog fractional-N PLL 100 includes a PFD 101, a charge pump 102, a low-pass filter (LPF) 103 serving as a loop filter, a voltage controlled oscillator 104, and a feedback divider (MMDIV) 105 controlled by a sigma-delta modulator 106 (also known as a delta-sigma modulator or DSM). Those elements are common to analog fractional-N PLLs. For example, PFD 101 is configured to detect the phases and frequencies of input reference signal 108 and loop feedback signal 115, and to generate output signal 118 that reflects the phase and frequency difference between signals 108 and 115. Charge pump 102 is configured to receive output signal 118 from PFD 101, and generate positive or negative current pulses 119 based on the sign of output signal 118. LPF 103 is configured to filter noises from output pulses 119 to generate control signal 120. VCO 104 is configured to generate loop output signal 121, and the frequency of loop output signal 121 is controlled by control signal 120. MMDIV 105 is configured to divide loop output signal 121 by a value provided by signal 136 from sigma-delta modulator 106. MMDIV 105 is then configured to send loop feedback signal 115, which is the divided version of loop output signal 121, back to PFD 101 as feedback of PLL 100. However, in addition to elements 101-106, analog fractional-N PLL 100 also includes a digital-to-time converter (DTC) 107 on the reference signal input 108 of PFD 101.

DTC 107 is configured to receive original reference signal 112 and generate reference signal 108 by delaying original reference signal 112 with a delay value controlled by delay signal 117 (as shown in dashed line), represented as X(n). DTC 107 is configured to receive delay signal 117 and convert delay signal 117 to an analog time delay so that original reference signal 112 can be delayed by the analog time delay to result in reference signal 108. The time delay value, represented by delay signal 117, varies because sigma-delta modulator 106 attempts to force MMDIV 105, which can divide only by an integer value, to mimic a fractional division. The mimicking of fractional division is performed by changing the integer division over time. To divide a signal by a non-integral value in the form of ‘M+Z/10’ with M, Z being integers, MMDIV 105 is controlled by sigma-delta modulator 106 to perform a division by M for N₁ clock cycles, and then perform a division by M+1 for N₂ clock cycles such that:

M×N₁+(M+1)×N₂=(M+Z/10)×(N₁+N₂)

In this way, MMDIV 105 is able to divide a signal by the non-integral value of ‘M+Z/10.’ For example, to mimic division by ‘2.1’, sigma-delta modulator 106 causes MMDIV 105, over ten consecutive clock cycles, to divide by ‘2’ nine times and then divide by ‘3’ once, so that “on average,” division by ‘2.1’ is performed. Sigma-delta modulator 106 is configured to receive an input of a desired factional value 126 (e.g., ‘M+Z/10’) and generate MMDIV control signal 136 in the form of integral values (e.g., M, M+1), which may vary per clock cycle as described above. For example, to mimic division by ‘2.1’, sigma-delta modulator 106 causes MMDIV 105, over ten consecutive clock cycles, to divide by ‘2’ nine times and then divide by ‘3’ once, so that “on average,” division by ‘2.1’ is performed. Sigma-delta modulator 106 is configured to receive an input of a desired factional value 126 (e.g., ‘M+Z/10’) and generate MMDIV control signal 136 in the form of integral values (e.g., M, M+1), which may vary per clock cycle as described above.

Delay (or error) signal 117 is the accumulated difference between the input desired fractional value 126 and the MMDIV control signal 136. The difference between input signal 126 representing the desired fractional value and MMDIV control signal 136, is determined at adder 146 (configured as a subtractor by flipping the sign of signal 136), which changes on each clock cycle based on the output of sigma-delta modulator 106 representing an integral divisor for the respective clock cycle, and is then accumulated over a number of clock cycles at accumulator 116, which in turn generates the delay signal is a signed number X(n). The magnitude of X(n) represents the delay, and the sign of X(n) represents whether the signal is to be advanced or retarded.

Delay signal 117 is then sent to DTC 107. DTC 107 converts delay signal 117, representing the delay introduced by MMDIV 105, to an analog time delay that is applied to the original reference signal 112. Thus loop feedback signal 115 is obtained by dividing loop output signal 121 a value provided by MMDIV control signal 105, and original reference signal 112 is delayed by a time value reflecting the difference between a desired division value and the actual MMDIV divisor. As a result, reference signal 108 (which is a delayed version of original reference signal 112) and loop feedback signal 115 are both adjusted in their respective phases by the same amount on average over a number of clock cycles, reducing quantization noise in the output of analog fractional-N PLL 100.

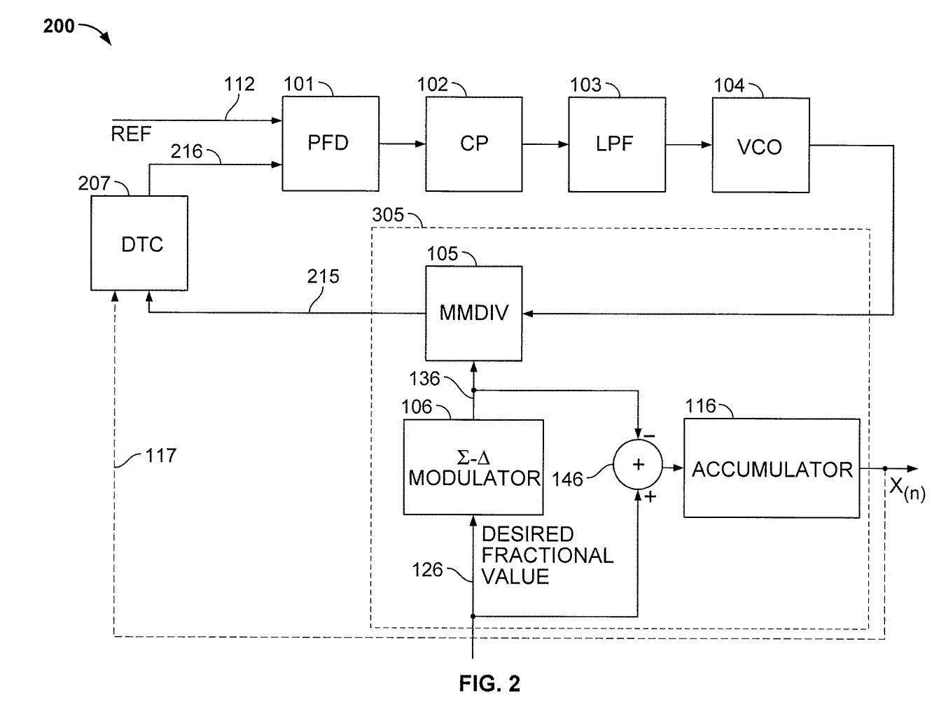

An alternative implementation of an analog fractional-N PLL 200 according to the subject matter of this disclosure, shown in FIG. 2, includes a PFD 101, a charge pump 102, a low-pass filter (LPF) 103 serving as a loop filter, a voltage controlled oscillator 104, a feedback divider (MMDIV) 105 controlled by a sigma-delta modulator 106, and a digital-to-time converter (DTC) 207 on the feedback signal input of PFD 101. Elements 101-106 are similar to those in FIG. 1. In this alternative implementation, DTC 207 is placed on loop feedback signal 215 that is fed back to PFD 101. DTC 207 is thus configured to convert the delay signal 117 (e.g., similar to signal 117 as discussed in connection with FIG. 1) into an analog time delay that is subtracted from the loop feedback signal 215 to obtain a delayed loop feedback signal 216. In this way, PFD 101 is configured to compare the original reference signal 112, and output signal 216 from DTC 207, which is a time-delayed version of loop feedback signal 215 from MMDIV 105.

In some embodiments, this “subtraction” of delay may actually be accomplished by further delaying the loop feedback signal 2015 by the difference between a complete period of the feedback signal and the delay, cancelling that delay relative to reference signal 108 and thereby reducing quantization noise in the output of analog fractional-N PLL 200.

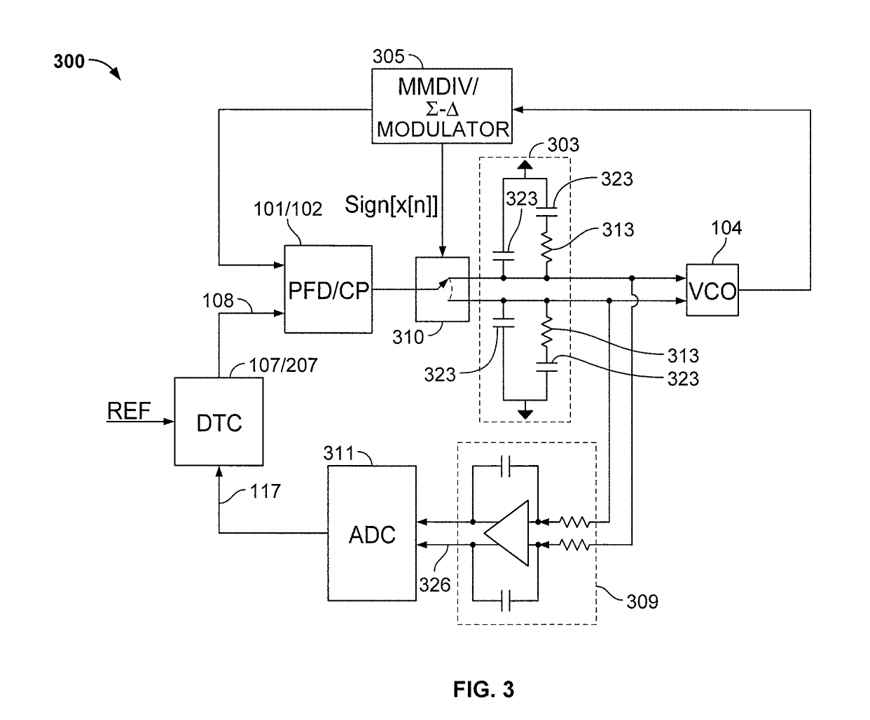

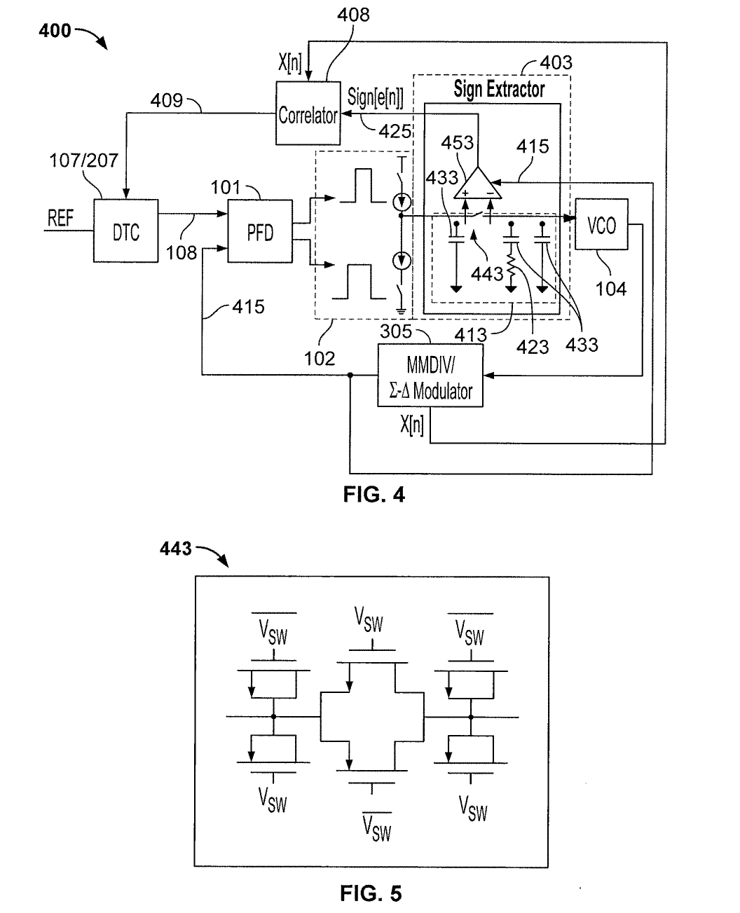

In both FIGS. 1 and 2, as DTC 107 or 207 is added to the analog fractional-N PLL, the gain introduced by DTC 107 or 207 is calibrated to adjust the settling time performance of the PLL. FIGS. 3 and 4 provide alternative implementations of circuitry for DTC gain calibration.

FIG. 3 provides an example block diagram showing circuitry representing an implementation of an analog fractional-N PLL 300 according to the subject matter of this disclosure, operating according to a signed-data least-mean-square (LMS) technique for deriving digital delay signal 117 that controls gain calibration of DTC 107/207. In this implementation 300, loop filter 303 includes resistors 313 and capacitors 323 arranged as shown. A signal representing the sign of error signal X(n) from MMDIV 105 as controlled by a sigma-delta modulator 106 (shown collectively at block 305) selects one of two paths through loop filter 303 and analog integrator 309 via switch 310. Loop filter 303 is configured to filter noise components of an output signal from PFD/CP 101, and the filtered signal from loop filter 303 is then integrated by the analog integrator 309 to generate an analog output signal 326. The arrangement of loop filter 303 and analog integrator 309 to achieve signed-data LMS for DTC gain calibration is further discussed in Swaminathan, A., et al., “A Wide-Bandwidth 2.4 GHz ISM Band Fractional-N PLL With Adaptive Phase Noise Cancellation,” IEEE Journal Of Solid-State Circuits, vol. 42, no. 12, pages 2639-50 (December 2007), which is hereby incorporated by reference herein in its entirety. However, because DTC 107/207 requires a digital input, analog-to-digital converter (ADC) 311 is provided to convert an analog output signal 326 from analog integrator 309 to the digital delay signal 117.

FIG. 4 provides an example block diagram showing circuitry representing an implementation of an analog fractional-N PLL 400 according to the subject matter of this disclosure, operating according to a signed-error LMS technique for deriving the digital time signal that controls gain calibration of DTC 107/207. In this implementation 400, loop filter 403, which is configured to filter noise from the output signal of charge pump 102, includes a second-order sample-hold low-pass filter 413 including resistor 423 and capacitors 433, as well as a switch 443 (shown in more detail in FIG. 5, where v_{sw} is the voltage across the switch), arranged as shown.

The output signal from PFD 101 and charge pump 102 may include an error or noise component. The error or noise component may be caused by the control signal 409, which is obtained from fractional division of the loop output, and thus passes on any rounding error in the fractional division—e.g., at MMDIV/sigma-delta modulator 305. The error signal component, when passed on from charge pump 102 to second-order sample-hold low-pass filter 413, may be first stored on capacitor 433 (on the left) and then redistributed to capacitors 433 (on the right) when switch 443 is closed. Comparator 453, clocked by feedback signal 415 signal (e.g., similar to loop feedback signal 115 in FIG. 1) from MMDIV 105 as controlled by a sigma-delta modulator 106 (again shown collectively at block 305), measures the voltage difference between opposite sides of switch 443 before switch 443 is closed. The voltage difference may be extracted as a sign signal 425 indicative of the sign of an error or noise component from the output of charge pump 102. Sign signal 425 is multiplied, in correlator 408, by the magnitude of X(n), which represents the delay introduced by MMDIV 105, to provide control signal 409 for DTC 107/207.

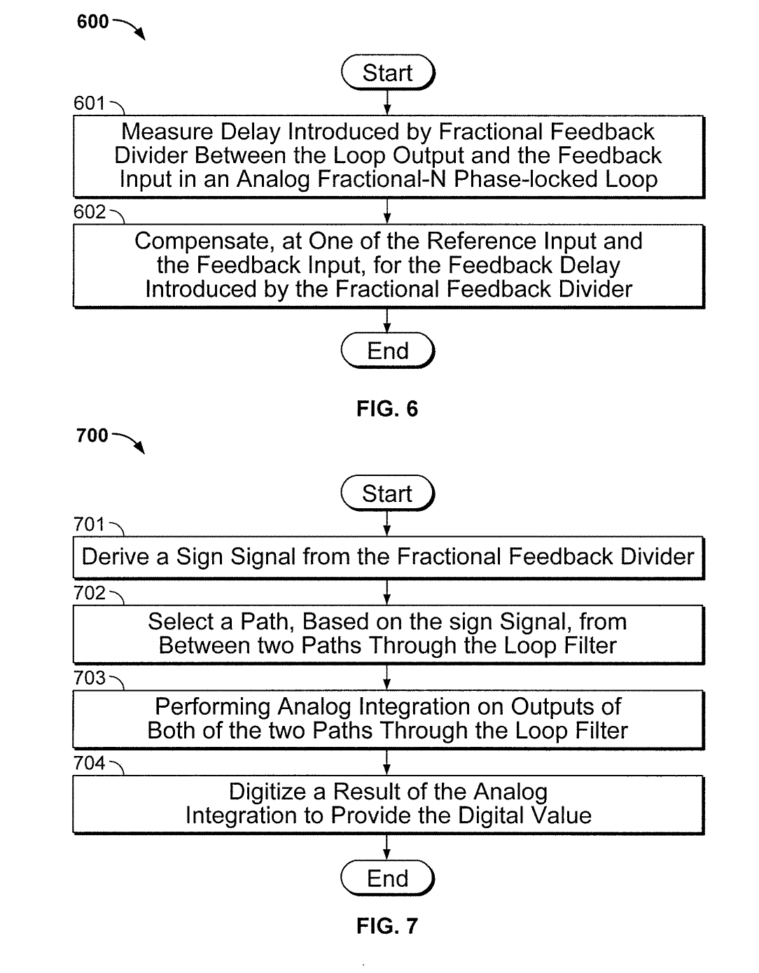

An implementation of a method 600 according to the subject matter of this disclosure, for reducing or cancelling quantization noise in an analog fractional-N PLL, is diagrammed in FIG. 6. At 601, delay introduced by the fractional feedback divider between the loop output and the feedback input in an analog fractional-N phase-locked loop is measured. At 602, the feedback delay introduced by the fractional feedback divider is compensated for at one of the reference input and the feedback input. For example, as shown in FIG. 1, the reference input (e.g., 112 in FIG. 1) is delayed by a time delay value that is generated based on the divisor used by the fractional feedback divider. As another example, as shown in FIG. 2, the feedback input (e.g., 215 in FIG. 2) is delayed by a time delay value that is generated based on the divisor used by the fractional feedback divider. In this way, at least one of the reference input and the feedback input is delayed by an amount similar to the feedback delay introduced by the fractional feedback divider, thus the cancelling the rounding error, i.e., the quantization noise, resulting from the fractional division.

FIG. 7 shows one variant 700 of the compensating at 602. At 701, a sign signal is derived from the fractional feedback divider. At 702, a path is selected, based on the sign signal, from between two paths through the loop filter. At 703, analog integration is performed on outputs of both of the two paths through the loop filter. At 704, the result of the analog integration is digitized to provide a digital signal as a control signal for a delay-to-time converter.

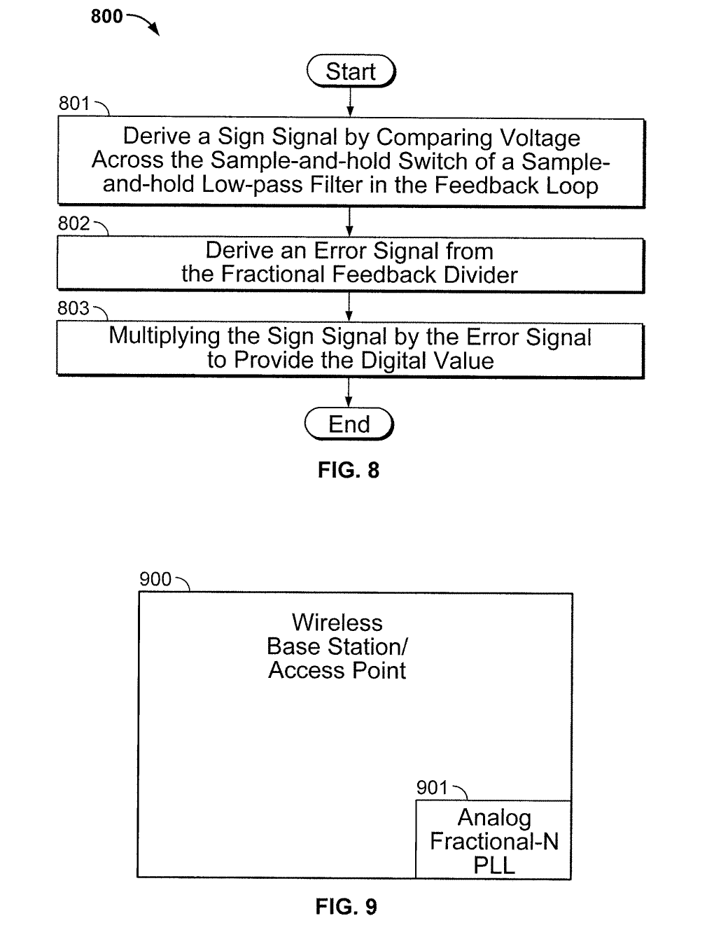

FIG. 8 shows another variant 800 of the compensating at 602. At 801, a sign signal (e.g., signal 425 in FIG. 4) inactive of the sign of an error or noise component of a signal being processed in the analog fractional-N PLL feedback loop, is derived by comparing voltages on both sides the sample-and-hold switch of a sample-and-hold low-pass filter (e.g., switch 443 in FIG. 4) in the feedback loop of the analog fractional-N PLL. At 802, an error signal (e.g., feedback signal 415 in FIG. 4) indicative of the rounding error inside a fractional feedback divider, is derived from the fractional feedback divider. At 803, the sign signal is multiplied by the error signal to provide a digital delay signal indicative of a delay value for delay-to-time converter.

An analog fractional-N PLL 901 according to an implementation of the subject matter of this disclosure is suitable for inclusion in a wireless transceiver such as a WiFi base station or access point 900, in accordance with an embodiment of the disclosure, as shown in FIG. 9.

Thus it is seen that an analog fractional-N PLL in which quantization noise has been reduced or cancelled, a method for reducing or cancelling quantization noise in an analog fractional-N PLL, and a compensation circuit for an analog fractional-N PLL, have been provided.

As used herein and in the claims which follow, the construction “one of A and B” shall mean “A or B.”

It is noted that the foregoing is only illustrative of the principles of the invention, and that the invention can be practiced by other than the described embodiments, which are presented for purposes of illustration and not of limitation, and the present invention is limited only by the claims which follow.

What is claimed is:

1. An analog fractional-N phase-locked loop, comprising:
an oscillator loop having:
a reference input, a feedback input, and a loop output, and
a fractional feedback divider configured to divide signals on the loop output by a divisor, wherein output of the fractional feedback divider is fed back to the feedback input; and
a compensation circuit coupled to one of the reference input and the feedback input, the compensation circuit configured to apply a time delay to the one of the reference input and the feedback input to compensate for delay introduced by the fractional feedback divider.

2. The analog fractional-N phase-locked loop of claim 1 wherein the compensation circuit is a digital-to-time converter configured to convert a digital delay signal into the time delay.

3. The analog fractional-N phase-locked loop of claim 2, wherein the digital-to-time converter is coupled to the reference input and is configured to delay signals on the reference input by the time delay to match feedback delay introduced by the fractional feedback divider.

4. The analog fractional-N phase-locked loop of claim 2, wherein the digital-to-time converter is coupled to the feedback input and subtracts the time delay from signals on the feedback input to cancel feedback delay introduced by the fractional feedback divider.

5. The analog fractional-N phase-locked loop of claim 2, wherein:
the oscillator loop further comprises a loop filter configured to filter out frequency noise components; and
the digital delay signal to control the digital-to-time converter is derived based at least in part on an output of the loop filter.

6. The analog fractional-N phase-locked loop of claim 5, wherein the analog fractional-N phase-locked loop further comprises:
an analog integrator configured to integrate the output of the loop filter to generate an analog delay signal; and
an analog-to-digital converter configured to digitize the analog delay signal thereby to provide the digital delay signal to control the digital-to-time converter.

7. The analog fractional-N phase-locked loop of claim 6 wherein:
a sign signal, representative of direction of phase mismatch, is derived from the fractional feedback divider;
the oscillator loop further comprises a switch configured to, based on the sign signal, select a path from between two paths through the loop filter; and
the analog integrator is connected to outputs of both of the two paths through the loop filter.

8. The analog fractional-N phase-locked loop of claim 5, wherein:
an error signal, representative of delay introduced by the fractional feedback divider, is output by the fractional feedback divider;
the loop filter is a sample-and-hold low-pass filter including a sample-and-hold switch; and
the analog fractional-N phase-locked loop further comprises:
a comparator connected across the sample-and-hold switch to derive a sign signal, and
a correlator configured to multiply the sign signal by the error signal to provide the control signal.

9. The analog fractional-N phase-locked loop of claim 1, wherein:
the divisor includes a fractional value; and
the fractional feedback divider comprises a feedback divider configured to divide signals on the loop output by a respective integral value at each respective clock cycle, and a sigma-delta modulator configured to generate the respective integral value at each respective clock cycle based on the divisor.

10. A wireless transceiver including the analog fractional-N phase-locked loop of claim 1.

11. A method of operating an analog fractional-N phase-locked loop, including an oscillator loop having a reference input, a feedback input, and a loop output, and having a fractional feedback divider configured to divide signals on the loop output by a divisor, wherein output of the fractional feedback divider is fed back to the feedback input, the method comprising:
measuring delay introduced by the fractional feedback divider; and
compensating for the feedback delay introduced by the fractional feedback divider by applying a time delay to the one of the reference input and the feedback input.

12. The method of claim 11, wherein:
the measuring comprises deriving a digital delay signal representative of the delay introduced by the fractional feedback divider; and
the compensating comprises converting the digital delay signal to the time delay.

13. The method of claim 12, wherein the compensating is performed by a digital-to-time converter coupled to the reference input, and comprises delaying signals on the reference input to match the feedback delay introduced by the fractional feedback divider.

14. The method of claim 12, wherein the compensating is performed by a digital-to-time converter coupled to the feedback input, and comprises subtracting delay from signals on the feedback input to cancel the feedback delay introduced by the fractional feedback divider.

15. The method of claim 12, wherein the deriving a digital delay signal is performed based at least in part on an output of a loop filter in the oscillator loop.

16. The method of claim 15, wherein the deriving a digital value comprises:
performing analog integration at the output of the loop filter; and
digitizing a result of the analog integration to provide the digital delay signal.

17. The method of claim 16 further comprising:
deriving a sign signal, representative of direction of phase mismatch between the reference input and the loop output, from the fractional feedback divider; and
selecting a path, based on the sign signal, from between two paths through the loop filter; wherein:
the analog integration is performed on outputs of both of the two paths through the loop filter.

18. The method of claim 15, wherein the loop filter is a sample-and-hold low-pass filter including a sample-and-hold switch, the method further comprising:
deriving a sign signal by comparing voltages on both sides of the sample-and-hold switch;
deriving an error signal indicative of a rounding error from the fractional feedback divider; and
multiplying the sign signal by the error signal to provide the digital value.

19. A compensation circuit for an analog fractional-N phase-locked loop including an oscillator loop having a reference input, a feedback input, a loop filter and a loop output, and having a fractional feedback divider in a feedback position between the loop output and the feedback input, the compensation circuit comprising:
circuitry that is configured to measure delay introduced by the fractional feedback divider; and
circuitry that is configured to compensate for the feedback delay introduced by the fractional feedback divider by applying a time delay to the one of the reference input and the feedback input.

20. The compensation circuit of claim 19 wherein the circuitry that compensates comprises a digital-to-time converter configured to convert a digital delay signal into the time delay.

21. The compensation circuit of claim 20 wherein:
the circuitry that measures comprises an analog integrator at an output of the loop filter; and
the analog integrator is configured to integrate the output of the loop filter to generate an analog delay signal.

22. The compensation circuit of claim 20 wherein:
the loop filter includes a sample-and-hold low-pass filter having a sample-and-hold switch; and
the circuitry that measures comprises:
a comparator across the sample-and-hold switch, the comparator being configured to generate a sign output from comparison of signals from both sides of the sample-and-hold switch, and
correlator circuitry configured to multiply the sign output of the comparator by an error signal from the fractional feedback divider to generate the digital delay signal for the digital-to-time converter.
